(19) United States
(12) Patent Application Publication
(10) Pub. No.: US 2006/0286385 A1
(43) Pub. Date: Dec. 21, 2006

(54) Method for producing and treating epoxide resin moulding materials

(75) Inventors: Heinz-Gunter Reichwein, Kamp-Lintfort (DE); Michael Schwab, Letmathe (DE); Jens Steinmann, Duisburg (DE); Gunda Kuhlmann, Hamm (DE); Frank Bayerl, Hagen (DE); Thomas Dressen, Oberhausen (DE)

Correspondence Address: HEDMAN & COSTIGAN P.C., 1185 AVENUE OF THE AMERICAS, NEW YORK, NY, 10036, US

(73) Assignee: BAKELITE AG, Ladenburg (DE)

(21) Appl. No.: 10/506,115

(22) PCT Filed: Feb. 19, 2003
(86) PCT No.: PCT/EP03/01639

§ 371 Date: Sep. 27, 2004

(30) Foreign Application Priority Data
Feb. 28, 2002 (DE) 102 08 644.3

(51) Int. Cl. B32B 27/38; H01L 21/56; C08L 63/00; B27N 3/00

(52) U.S. Cl. 428/413; 438/127; 523/400; 264/109

(57) ABSTRACT

A method for the preparation and processing of epoxy resin molding compositions comprised of epoxy resins, hardeners, fillers and additives, by mixing the epoxy resins with the other components of the composition in a high-speed mixer and granulating the same and homogenizing the resultant free-flowing granules shortly prior to shaping and curing under pressure.

The invention relates to a novel method for the preparation and processing of moulding compositions based on epoxy resins.

Epoxy resin moulding compositions are granules composed of epoxy resin, of hardener, and also of fillers and of additives, which can be processed without admixture of any additive to give mouldings which can be cured by heat. The resultant mouldings have good mechanical and electrical properties.

There are various methods (cf. Kunststoff Handbuch [Plastics Handbook] Volume 10 “Duroplaste” [“Thermosets”], 2nd Edition, Hanser Verlag 1988, pp. 338-342) for the preparation of epoxy resin moulding compositions:
The other fillers and additives are mixed into a liquid mixture of epoxy resin and hardener. The epoxy resins are permitted to undergo preliminary reaction at a slightly raised temperature until the composition is non-tack and free-flowing at room temperature. Despite good wetting of the fillers, this method has the disadvantage that the control of the preliminary reaction is not precisely reproducible, the result being that the reactivity of the moulding compositions obtained differs from batch to batch. These moulding compositions are moreover not storage-stable.
In what is known as the dry mixing method, solid epoxy resins and hardener are ground at room temperature with the other constituents of the moulding composition and intimately mixed. The powder then has to be mechanically compacted and granulated. In this composition, resin and hardener are in the form of small particles alongside one another. This gives the compositions good storage stability. However, with this method the wetting of the fillers is unsatisfactory, the result being that the only moulding compositions which can be prepared are those with relatively low filler content, and these moreover give only mouldings with rather unsatisfactory mechanical properties.
To improve wetting of the fillers, therefore, the melt method homogenizes a premix composed of solid epoxy resin, of hardener, of fillers and of additives in the form of a melt, and then cools and granulates the same. However, curing reactions again occur prior to completion of this melt-homogenization process, which is technologically complicated, and reduce the storage stability of the moulding composition, and lead to a composition which very rapidly loses its quality through storage. This can be avoided if each of resin and hardener is separately homogenized with fillers and additives in melts, and are then mixed in powder form. However, there is then again a fall in the level of mechanical properties of the resultant mouldings.

It is therefore an object of the present invention to provide a simple, quick method which can prepare epoxy resin moulding compositions and which can prepare storage-stable moulding compositions with high filler content, these giving, after shaping and curing, mouldings with very good mechanical and electrical properties.

The object is achieved by way of a method for the preparation and processing of epoxy resin moulding compositions according to Claims 1 to 7. The moulding compositions prepared by the method are particularly suitable for the production of mouldings by the reaction injection moulding method, for the encapsulation of electronic or electrical components or component parts, or else for the production of mechatronics components, as claimed in Claims 8 to 10.

The invention achieves the object by mixing all of the constituents of the moulding composition together in a high-speed mixer and processing them to give loose, free-flowing granules. The direct further processing of these granules as a moulding composition for the production of mouldings in the known manner by press-moulding in a mould does not give high-quality mouldings, because the homogenization is inadequate. However, it has been found that the granules have the property of forming a flowable composition under pressure. According to the invention, this is utilized by homogenizing the granules shortly prior to shaping and curing under pressure. In practice, the granules, which are not yet adequately homogenous, are forced through a continuous mixer upstream of the mould, under pressure and, where appropriate, with heating, and thereby homogenized, shortly prior to their introduction into the mould. Surprisingly, this is also successful with moulding compositions whose filler content is up to 95% by weight, based on the entire composition.

The granules are prepared very quickly and easily. The granules can be stored and do not clump together in the pack during normal storage, but remain free-flowing. Application of pressures >5 bar, for example those arising during passage through transport devices, such as extruder screws or piston pumps, is required in order to plasticize these mixtures and permit their homogenization in continuous mixers. The resultant homogeneous moulding composition is then directly injected into the mould. Another advantage of the inventive method is that not only the mixing machines, but also the units of the apparatus such as the devices needed to generate pressure and the continuous mixers, are machines familiar in the plastics-processing industry, and can easily be installed upstream of a mould. There is no substantial resultant alteration to the process usually used hitherto to manufacture mouldings.

The make-up of the epoxy resin moulding compositions prepared according to the invention is substantially the same as that of the epoxy resin moulding compositions conventionally used hitherto. Epoxy resins which may be used are any of the epoxy compounds having at least two epoxy groups per molecule and having a melting range below 70° C. Preference is given to epoxy compounds which are liquid at room temperature, examples being diglycidyl ethers of bisphenols, or pre-extended resins based on bisphenol A diglycidyl ethers. Particular preference is given to low-viscosity resins, such as epoxy resins based on cycloolefins or tetraglycidyldianiline, or else mixtures of solid epoxy resins, e.g. of epoxidized novolaks, with what are known as reactive diluents. The epoxy resins may, where appropriate, have been modified with other polymers, e.g. polyesters, acrylates, silicon polymers or polyvinyl derivatives.

Hardeners used comprise latent hardeners known per se, e.g. alkyl-substituted aromatic amines, polycarboxylic acids, polycarboxylic anhydrides, BCl₃ complexes or BF₃ complexes, latent heterocompounds based on nitrogen or phosphorus or metal complex compounds. Other latent hardeners, however, are microencapsulated hardeners. For these, hardeners which in free form cure the epoxy resins at temperatures as low as room temperature, examples being aliphatic or aromatic amines or polyamines, novolaks or imidazole derivatives, are encapsulated by an inert material. Under the conditions of processing of the granules, the capsule walls are broken down either by the heat introduced or by the shear forces arising during homogenization, and the hardener is released and homogenized with the remainder of the moulding composition mixture. The amount of the hardener used is selected in the manner known per se so as to be sufficient for complete curing of the epoxy compounds.

Fillers which may be used are any of the inorganic and/or organic fillers which are usual for moulding compositions of this type and which have the particle sizes usually used. Examples are chalks, which may be untreated or have been hydrophobicized, dolomite, silica, which may have been precipitated or ground, wollastonite, mica, talc, silicates, clays, titanium dioxide, lithopones, aluminium oxide hydrate, antimony trioxide, and also cellulose powders or polyamide powders. However, use may also be made of fibres as fillers providing particular reinforcement, in particular short fibres with an average length of from 0.5 to 4 mm. Examples of these fibres are glass fibres, ceramic fibres, aramide fibres, cellulose fibres, polyester fibres, polyamide fibres and carbon fibres. The amount used of the fillers is up to 95% by weight, preferably up to 85% by weight, based on the entire moulding composition.

Other materials which may be mixed into the epoxy resin moulding compositions prepared according to the invention are the familiar amounts of conventional additives, such as lubricants or release agents, e.g. waxes, metal soaps or substituted fatty amides, pigments, flexibilizers, coupling reagents, accelerators or flame retardants.

Ideally, all of the constituents of the epoxy resin moulding compositions are simultaneously mixed with one another. For practical reasons, it is preferable here to form an initial charge from the liquid constituents of the compositions and add the solid ingredients in any desired sequence.

The mixing procedure takes place in a high-speed mixer, e.g. in a multishaft dissolver, a fluidized-bed mixer, a turbo internal mixer, or a high-performance centrifugal mixer. Preference is given to those high-speed mixers which also provide the opportunity of controlling the temperature of the material undergoing mixing, with the result that the temperature rise due to the energy introduced is restricted in such a way that the temperature of the mixture can be held below the initiation temperature for the curing reaction of the epoxy resin. Where appropriate, a cooling mixer may be installed downstream of the mixer. Within a short mixing time, and if use if made of fluidized-bed or high-performance centrifugal mixers within a mixing time of less than one minute, the as yet inhomogeneous moulding composition gives loose granules which are sufficiently pressure-resistant for handling and can be stored in this form at room temperature for a plurality of months. The mixing procedure is to be terminated once the granules have formed, because the mixture clumps if the mixing time is prolonged.

These granules may theoretically be used as a moulding composition for the production of mouldings. However, because the mixing procedure does not give a very high level of wetting of the fillers, and does not give the mixture sufficient homogeneity, the mechanical properties of the resultant mouldings are unsatisfactory. According to the invention, therefore, the granules are homogenized shortly prior to the shaping and curing under pressure. This is achieved by using a conveying device which increases pressure, for example a piston pump or a screw, to force the granules through a continuous mixer upstream of the mould, where appropriate with heating to a temperature which is below the initiation temperature for the curing of the epoxy resin or, respectively, below the melting point of the capsule wall material of any encapsulated hardeners used. Continuous mixers with incorporated screw are continuously operating single-screw or multiscrew mixers, or co-kneaders. A simpler, but equally effective, method of achieving homogenization uses a static mixer as the continuous mixer upstream of the mould, with, upstream of the static mixer, a conveying device which generates pressure and which plastifies the granules and forces them through the static mixer.

The moulding compositions prepared according to the invention are suitable for any of the applications in which epoxy resin moulding compositions are [lacuna]. However, they are particularly suitable for the production of mouldings in the reaction injection moulding method, for the encapsulation of electronic or electrical components or component parts, or else for the production of mechatronics components.

1. A method for the preparation and processing of epoxy resin molding compositions comprising epoxy resins, hardeners, fillers and additives, comprising mixing the epoxy resins with the other components of the composition in a high-speed mixer, granulating the mixture and homogenizing the resulting free-flowing granules shortly prior to shaping and curing under pressure.

2. The method of claim 1, wherein the epoxy resins used are liquid at room temperature.

3. The method of claim 1 wherein the hardeners used are latent epoxy resin hardeners.

4. The method of claim 1 wherein the mixing of the constituents takes place in a mixer selected from the group consisting of a fluidized-bed mixer, turbo internal mixer or high-performance centrifugal mixer.

5. The method of claim 1 wherein the homogenization of the composition takes place in a continuous mixer upstream of the mold.

6. The method of claim 1 wherein the homogenization of the composition takes place in a static mixer upstream of the mold.

7. The method of claim 5 wherein upsteam of the continuous mixer there is a screw or piston pump with the aid of which the granules are compacted and forced through the continuous mixer.

8-10. (canceled)

11. In the encapsulation of electrical or electronic components or component parts, the improvement comprising using a composition prepared by the method of claim 1.

12. In the production of mechatronic components, the improvement comprising using the composition prepared by the method of claim 1.

13. In a process for producing molding by an injection molding process, the improvement comprising a composition prepared by the method of claim 1.

14. A molding composition produced by the method of claim 1.
